(19) United States
(12) Patent Application Publication
(10) Pub. No.: US 2025/0149091 A1
(43) Pub. Date: May 8, 2025

(54) SEMICONDUCTOR DEVICES AND OPERATION METHODS THEREOF, AND MEMORY SYSTEMS

(71) Applicant: Wuhan Xinxin Semiconductor Manufacturing Co., Ltd., Wuhan (CN)

(72) Inventor: Yanqiang DU, Wuhan (CN)

(73) Assignee: Wuhan Xinxin Semiconductor Manufacturing Co., Ltd., Wuhan (CN)

(21) Appl. No.: 18/938,364

(22) Filed: Nov. 6, 2024

(30) Foreign Application Priority Data
Nov. 7, 2023 (CN) 202311483848.X

(51) Int. Cl. G11C 16/08; G11C 5/14; G11C 16/26; G11C 16/32

(52) U.S. Cl. CPC G11C 16/08; G11C 5/145; G11C 16/26; G11C 16/32

(57) ABSTRACT

The present disclosure provides a semiconductor device and an operation method thereof, and a memory system. The semiconductor device includes a mode detection circuit and a charge pump. The mode detection circuit provides a first mode enable signal corresponding to a first state mode of the semiconductor device and provides a second mode enable signal corresponding to a second state mode of the semiconductor device. The charge pump operates in a first operation mode, in which a first output current is generated, based on the first mode enable signal, or operates in a second operation mode, in which a second output current is generated, based on the second mode enable signal. The first state mode includes an intra-word-line access state in which a continuous access is performed on memory cells on a same word line.

### RELATED APPLICATION

This application is a Paris Convention, which claims the benefit of priority of Chinese Patent Application No. 202311483848.X filed on Nov. 7, 2023. The contents of the above application is all incorporated by reference as if fully set forth herein in its entirety.

### FIELD AND BACKGROUND OF THE INVENTION

The present disclosure relates to semiconductor device technologies, and in particular, to semiconductor devices and operation methods thereof, and memory systems.

A flash memory (Flash) has a data storage function and includes a NOT-AND (NAND) flash memory and a NOT-OR (NOR) flash memory. However, both the NAND flash memory and the NOR flash memory have issues with power consumption. Power consumption has always been an important indicator of flash memories, especially for mobile devices powered by batteries. In addition, a reading operation is the most common operation performed on a flash memory. Therefore, how to reduce power consumed by the reading operation is an urgent problem to be solved.

### SUMMARY OF THE INVENTION

The present disclosure provides a semiconductor device, including:
a mode detection circuit configured to provide a first mode enable signal corresponding to a first state mode of the semiconductor device and provide a second mode enable signal corresponding to a second state mode of the semiconductor device; and
a charge pump configured to operate in a first operation mode, in which a first output current is generated, based on the first mode enable signal, or to operate in a second operation mode, in which a second output current is generated, based on the second mode enable signal;
wherein the first state mode comprises an intra-word-line access state in which a continuous access is performed on memory cells on a same word line.

The present disclosure further provides an operation method of a semiconductor device, including:
providing a first mode enable signal corresponding to a first state mode of the semiconductor device, and providing a second mode enable signal corresponding to a second state mode of the semiconductor device;
setting an intra-word-line access state, in which a continuous access is performed on memory cells on a same word line, as the first state mode; and
enabling a charge pump of the semiconductor device to operate in a first operation mode, in which a first output current is generated, based on the first mode enable signal, or to operate in a second operation mode, in which a second output current is generated, based on the second mode enable signal.

The present disclosure further provides a memory system including the semiconductor device as described above and a controller configured to control the semiconductor device.

### BRIEF DESCRIPTION OF THE DRAWINGS

To describe the technical solutions of some embodiments of the present disclosure more clearly, the following briefly introduces the accompanying drawings required for describing the embodiments. Apparently, the accompanying drawings in the following description show only some embodiments of the present disclosure, and a person skilled in the art can still derive other drawings from these accompanying drawings without inventive efforts.

FIG. 1 is a schematic block diagram of an exemplary memory according to some embodiments of the present disclosure.

FIG. 2A is a schematic diagram of a circuit of a storage array in the memory shown in FIG. 1.

FIG. 2B is a schematic diagram of another embodiment of the circuit of the storage array in the memory shown in FIG. 1.

FIG. 3 is a schematic block diagram of a voltage generator in the memory shown in FIG. 1.

FIG. 4A is a schematic block diagram of another embodiment of the voltage generator in the memory shown in FIG. 1.

FIG. 4B is a schematic block diagram of yet another embodiment of the voltage generator in the memory shown in FIG. 1.

FIG. 5 is a schematic flowchart of an operation method of a semiconductor device according to some embodiments of the present disclosure.

FIG. 6 is a schematic block diagram of a memory system according to some embodiments of the present disclosure.

### DESCRIPTION OF SPECIFIC EMBODIMENTS OF THE INVENTION

Some embodiments of the present disclosure will be described in detail below in connection with the accompanying drawings. The embodiments are described for illustrative purposes only and are not intended to limit the present disclosure.

In the description of the present disclosure, it should be understood that orientation or position relationships indicated by the terms such as “on”, and “under” are based on orientation or position relationships shown in the accompanying drawings, and are used only for ease and brevity of illustration and description of the present disclosure, rather than indicating or implying that the mentioned apparatus or component needs to have a particular orientation or needs to be constructed and operated in a particular orientation. Therefore, such terms should not be construed as limiting of the present disclosure. In addition, terms “first” and “second” are used merely for the purpose of description and shall not be construed as indicating or implying relative importance or implying a quantity of indicated technical features. Therefore, the feature limited by “first” or “second” may explicitly or implicitly include one or more of such features. In the descriptions of the present disclosure, “a plurality of” means two or more, unless otherwise definitely and specifically limited.

The present disclosure may repeat reference numerals or reference signs in different embodiments. Such repetition is for the purposes of simplicity and clarity, and does not by itself indicate relationships between various embodiments and/or arrangements discussed.

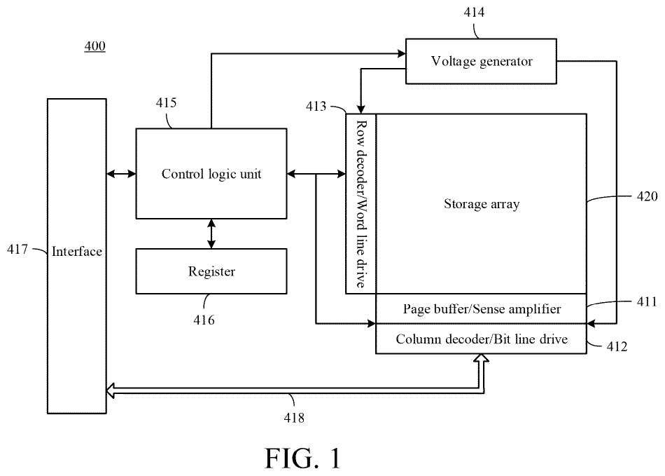

First, refer to FIG. 1. FIG. 1 is a schematic block diagram of a semiconductor device according to some embodiments of the present disclosure, in which a memory 400 is used as an exemplary semiconductor device. The memory 400 includes a storage array 420 and other peripheral circuits (not numbered). As shown in FIG. 1, the peripheral circuits may include at least circuits other than the storage array 420, such as a page buffer/sense amplifier 411, a column decoder/bit line drive 412, a row decoder/word line drive 413, a voltage generator 414, a control logic unit 415, a register 416, an interface 417, and a data bus 418. It should be understood that, in some embodiments, the peripheral circuits may further include other circuits that are not shown in FIG. 1.

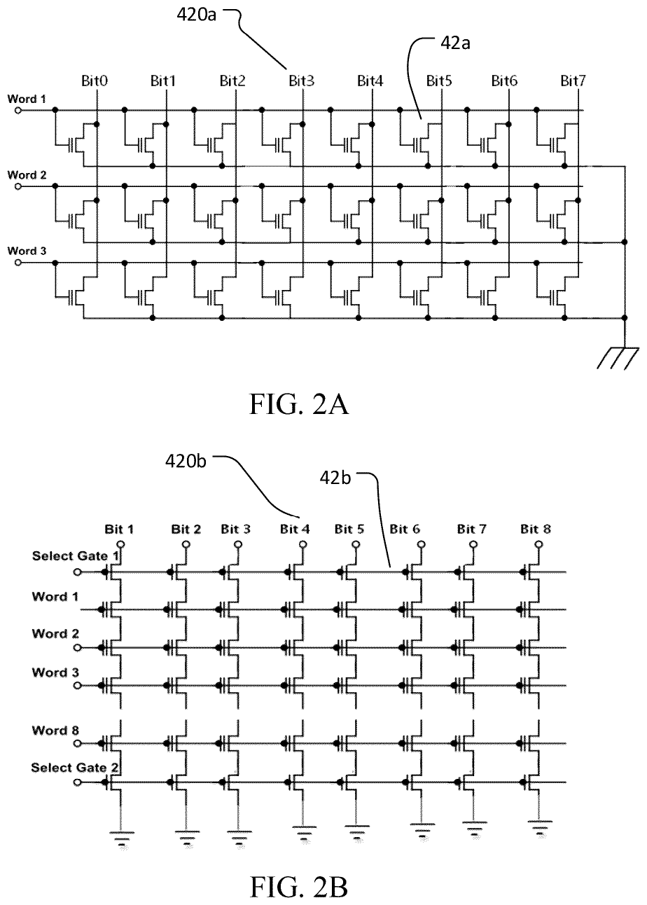

The block diagram as shown in FIG. 1 is applicable to, for example, a two-dimensional (2D) or three-dimensional (3D) flash memory (e.g., a NOT-AND (NAND) flash, a NOT-OR (NOR) flash) or a random access memory (RAM) (e.g., a dynamic RAM (DRAM)). These memories are different in their storage arrays 420. Therefore, the storage array 420 may be a storage array of, for example, 2D or 3D flash memories (NAND/NOR flash) or dynamic random access memories (DRAMs). The RAM may include a DRAM, a phase change RAM (PCRAM) a ferroelectric RAM (FeRAM), a magnetic RAM (MRAM), or the like. The storage array 420 has at least one giant block (Giant Block, GB) storage platform, and the storage platform includes at least a plurality of memory cells arranged in an array (referring to FIG. 2A and FIG. 2B). The plurality of memory cells may be arranged in a manner suitable for a 2D or 3D structure, or may be adaptable for a NAND, NOR, or DRAM architecture.

The page buffer/sense amplifier 411 may be configured to read data from the storage array 420, and program (which is also referred to as “write”) data into the storage array 420, based on a control signal from the control logic unit 415. In some embodiments, the page buffer/sense amplifier 411 may store data which is to be programmed into a memory page of the storage array 420. In some other embodiments, the page buffer/sense amplifier 411 may further perform a sensing operation on a low power signal that is from a bit line (BL) and represents data stored in the memory cells, and amplify a small voltage swing of the low power signal to a recognizable logic level in a reading operation. The page buffer/sense amplifier 411 may be arranged or combined in a different way depending on a type of the storage array 420 and a design of the bit lines (BLs). For example, the page buffer/sense amplifier 411 may be a plurality of page buffers/sense amplifiers 411 corresponding to a plurality of groups of bit lines.

The column decoder/bit line drive 412 may be configured to be controlled by the control logic unit 415, and select one or more columns of memory cells by applying a bit line voltage generated by the voltage generator 414. Similarly, the column decoder/bit line drive 412 may be arranged or combined in a different way depending on the type of the storage array 420 and the design of the bit lines (BLs), for example, there may be a plurality of column decoders/bit line drives 412.

The row decoder/word line drive 413 may be configured to be controlled by the control logic unit 415 to select different memory cells from the storage array 420. The row decoder/word line drive 413 may further be configured to drive a word line (WL) by applying a word line voltage generated by the voltage generator 414. Similarly, the row decoder/word line drive 413 may be arranged or combined in a different way depending on the type of the storage array 420 and the design of the bit lines (BLs), for example, there may be a plurality of row decoders/word line drives 413.

Therefore, the voltage generator 414 includes a charge pump. The charge pump may be configured to be controlled by the control logic unit 415, and generate the word line voltage and the bit line voltage to be supplied to the storage array 420 and a required current. However, it should be understood that the charge pump may be disposed at any position in the semiconductor device. Therefore, the voltage generator herein includes, in a broad sense, charge pumps at any position and their related circuits.

The control logic unit 415 may be coupled to each circuit of the peripheral circuits 410 (such as the page buffer/sense amplifier 411, the column decoder/bit line drive 412, the row decoder/word line drive 413, and the voltage generator 414), and control operations of said each circuit.

The register 416 may be coupled to the control logic unit 415, and may include at least a state register, a command register, and an address register, to storage state information, an operation code (OP code), and an address for control of operations of the foregoing circuits.

The interface 417 may be coupled to the control logic unit 415, and serve as a control buffer to perform operations of buffering a control command received from the controller in FIG. 1 and relaying the command to the control logic unit 415, and perform operations of buffering state information received from the control logic unit 415 and relaying the state information to an outer controller (not shown). In addition, the interface 417 may further be coupled to the column decoder/bit line drive 412 via the data bus 418, and serve as a data input/output (I/O) interface and a data buffer to perform operations of buffering data and relaying the data to the storage array 420, and perform an operation of relaying or buffering the data from the storage array 420.

In some embodiments, the storage array 420 may be of a NOR or NAND flash memory architecture, or may be, for example, a 1TIC or 1TXC memory architecture (wherein T represents a transistor, C represents a capacitance memory cell, and X represents a quantity). In addition, the storage array may be a 2D architecture or a 3D architecture. Therefore, embodiments of the present disclosure are merely examples.

FIG. 2A is a schematic diagram of a circuit of a NOR storage array. FIG. 2A only shows a storage array including three rows of word lines and eight columns of bit lines, that is, the word lines include word lines Word 1, Word 2, and Word 3, and the bit lines include bit lines Bit 0, Bit 1, Bit 2, Bit 3, Bit 4, Bit 5, Bit 6, and Bit 7. It should be understood that a quantity of the word lines and a quantity of the bit lines may be determined based on a storage capacity of a memory. A bit line represents a bit, Bit 0 to Bit 7 in FIG. 2A are a total of 8 bits and represent a byte. A word line represents a memory page. A memory page with a capacity of 1 KB requires 1024 bytes, that is, 1024×8 bit lines. To achieve a capacity of 1 MB, for example, 1024 word lines may be configured with to construct 1024 memory pages, that is, 1024 KB. Therefore, the configuration of memory cells in FIG. 2A is merely described as an example.

When a reading operation is performed, command information and address information are sent to the control logic unit 415 after data is entered through the interface 417. The control logic unit 415 decodes the address information by using the row decoder 413 and the column decoder 412 to obtain a word line and bit lines corresponding to the address, so as to locate locations of memory cells 42a to be read, for example, word line Word 1 and bit lines Bit 0 to Bit 7 to be read in sequence, and then data of this byte is read by the sense amplifier 411 sequentially. It should be understood that different read addresses may be on a same word line but bit lines of different bytes.

FIG. 2B is a schematic diagram of a circuit of a NAND storage array. FIG. 2B only shows a storage array including eight rows of word lines and eight columns of bit lines, that is, the word lines include word lines Word 1 to Word 8, and the bit lines include bit lines Bit 1 to Bit 8. It should be understood that, similar to a NOR flash memory, a quantity of the word lines and a quantity of the bit lines may be determined based on a storage capacity of a memory. A bit line represents a bit, Bit 1 to Bit 8 in FIG. 2B are a total of 8 bits and represent a byte. A word line represents a memory page. A memory page with a capacity of 1 KB requires 1024 bytes, that is, 1024×8 bit lines. To achieve a capacity of 1 MB, for example, 1024 word lines may be configured with to construct 1024 memory pages, that is, 1024 KB. Therefore, the configuration of memory cells in FIG. 2B is merely described as an example.

Other architectures of storage arrays may be 2D or 3D memory architectures. Such architectures are known to a person skilled in the art, and therefore are not described herein again and are not intended to limit an application scope of the present disclosure. These architectures, as long as being applicable to the technical ideas of the present disclosure, fall within the scope of the present disclosure. Therefore, in the following embodiments, a 2D NOR flash memory architecture is used for description as an example, but this does not indicate that the present disclosure is limited to a 2D NOR flash memory architecture.

Power consumption is an important indicator of memories, especially for NOR flash memories and mobile devices powered by batteries. The reading operation is a most common operation performed on a NOR flash. Therefore, how to reduce power consumed by reading is an urgent problem to be solved.

When the NOR flash memory is in a standby mode, the control logic unit 415 enables a charge pump in a standby mode in the voltage generator 414 to generate a voltage higher than that of a power source, and periodically refreshes, through a clock signal with a special frequency, a switch, and a capacitor, the charge pump that output a working voltage. When a user inputs a reading instruction, the charge pump (if in a standby mode) is turned off; or the charge pump (if in a working mode) starts to work, and generates and maintains a same voltage as that in the standby mode. A working current of the charge pump in the working mode is much larger than a working current of the charge pump in the standby mode, and a refresh frequency of the charge pump in the working mode is also much higher than a refresh frequency of the charge pump in the working mode. This greatly increases power consumed by the circuit. It should be understood that the working mode herein refers to a mode in which a particular operation, such as reading or programming, is performed, and the working current refers to an output current, especially a largest output current, during the particular operation.

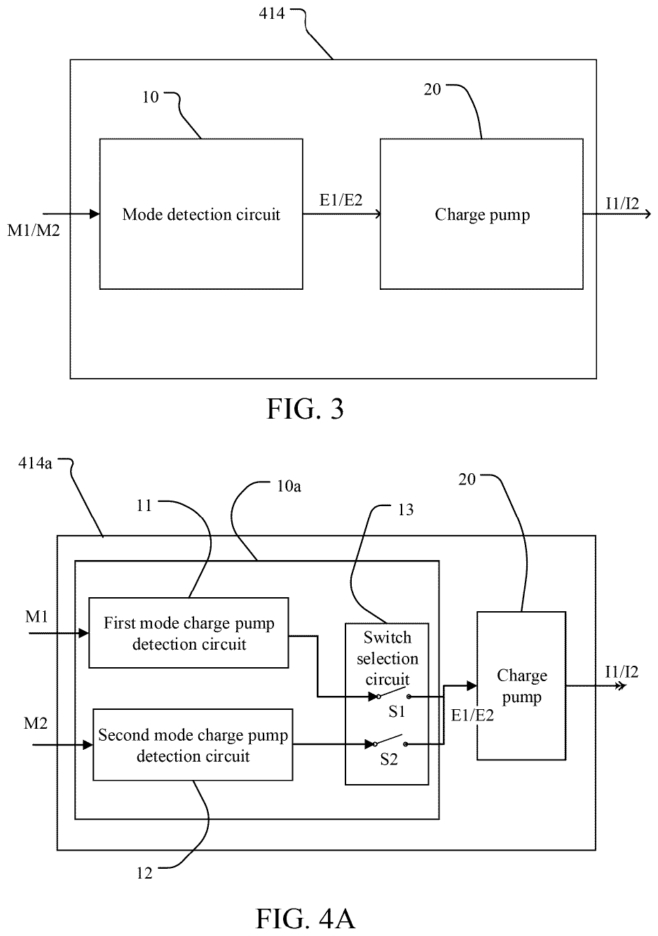

To address the issue of power consumption, FIG. 3 discloses a schematic block diagram of a semiconductor device according to some embodiments of the present disclosure, in which the voltage generator 414 is used as an exemplary semiconductor device.

As shown in FIG. 3, the semiconductor device according to some embodiments of the present disclosure includes a mode detection circuit 10 and a charge pump 20. The mode detection circuit 10 is configured to provide a first mode enable signal E1 corresponding to a first state mode M1 of the semiconductor device and to provide a second mode enable signal E2 corresponding to a second state mode M2 of the semiconductor device. The charge pump 20 is configured to be in a first operation mode, in which a first output current I1 is to be generated, based on the first mode enable signal E1, or to be in a second operation mode, in which a second output current I2 is to be generated, based on the second mode enable signal E2. The first state mode M1 includes an intra-word-line access state in which a continuous access is performed on memory cells 42a on a same word line.

In some embodiments, the second state mode M2 includes an inter-word-line access state in which a continuous access is performed on memory cells 42a on different word lines.

In some embodiments, the first state mode M1 further includes a standby state, and the first operation mode includes a standby mode.

In some embodiments, the second state mode M2 includes a working state in which a reading instruction is received, the continuous access is a continuous reading operation, and the second operation mode includes a working mode.

In some embodiments, the first output current I1 is smaller than the second output current I2. The first output current described herein refers to a largest current output value in the first operation mode, but not a constant current value. A person skilled in the art can understand that the largest output current and power consumption of the charge pump in the first operation mode are smaller than those in the second operation mode.

In some embodiments, the charge pump 20 works at a first refresh frequency based on the first mode enable signal E1, or works at a second refresh frequency based on the second mode enable signal E2, and the first refresh frequency is lower than the second refresh frequency.

In some embodiments, the mode detection circuit 10 can receive a state of a state logic (not shown) from the control logic unit 415 or of a memory 400 provided by the register 416, to detect the current state of the memory 400. For example, if the memory 400 is in a standby state waiting for receiving a command, the mode detection circuit 10 sets the standby state as the first state mode M1, and outputs the first mode enable signal E1. It should be understood that, in some embodiments, the mode detection circuit 10 may receive the first state mode signal M1 to determine a state mode, without performing detection.

If the control logic unit 415 receives a reading instruction, the state of the state logic (not shown) from the control logic unit 415 or of the memory 400 provided by the register 416 is a reading state, and the control logic unit 415 sends a voltage setting instruction to the voltage generator 414 and sends address information to the row decoder 413 and the column decoder 412. In this case, after receiving the voltage setting instruction or the reading state provided by the state logic, the mode detection circuit 10 sets the state mode of the memory/semiconductor device as the second state mode M2, and outputs the second mode enable signal E2. It should be understood that, in some embodiments, the mode detection circuit 10 may receive a second state mode signal M2 to determine a state mode, without performing detection.

Furthermore, the control logic unit 415 can determine a word line location of an address after receiving first address information in the reading command, and determine whether the word line location in next address information is changed when receiving the next address information. If the word line location is not changed, the control logic unit 415 provides first mark information, and the mode detection circuit 10 receives the first mark information and outputs the first mode enable signal E1. If the word line changes, the control logic unit 415 provides second mark information, and the mode detection circuit 10 receives and detects the second mark information, and outputs the second mode enable signal E2.

The foregoing embodiments are examples in which the control logic unit 415 detects whether there is a change in the word line. The detection may alternatively be performed by the mode detection circuit 10. This is not limited herein. Therefore, in some embodiments, the mode detection circuit 10 may be the first mode detection circuit or the second mode detection circuit after receiving the first/second state mode signal M1/M2. In some embodiments, the mode detection circuit 10 may be the first mode detection circuit or the second mode detection circuit after detecting the first/second state mode signal M1/M2.

In addition, in some embodiments, the mode detection circuit 10 is further configured to detect an output voltage and an output current of the charge pump 20, to determine whether output of the charge pump 20 meets requirements. For example, the mode detection circuit 10 may include an output voltage feedback circuit and a comparator (not shown), to determine whether output of the charge pump 20 meets requirements and then send an enable signal.

Next, after receiving the first mode enable signal E1 or the second mode enable signal E2 from the mode detection circuit 10, the charge pump 20 operates in the first operation mode, in which the first output current I1 is generated, based on the first mode enable signal E1, or operates in the second operation mode, in which the second output current I2 is generated, based on the second mode enable signal E2. It should be understood that the voltage generator 414 sends an output via the charge pump 20 to a word line determined through the decoding of the row decoder 413, so that the row decoder 413 can output a required output voltage and current through a selected word line.

In some embodiments, when there is a change in the word line, that is, in a case of an inter-word-line access which involves an ordinary operation in the second state mode M2, the charge pump 20 receives the second mode enable signal E2 to operate in the second operation mode, and provides a large current to charge a new word line. When there is no change in the word line, that is, in a case of an intra-word-line access in which the operation is set as special operation, and in the first state mode, the charge pump 20 receives the first mode enable signal E1 to operate in the first operation mode and provides a small output current, thereby reducing power consumption. In this case, because the word line has already been powered, providing a small current can meet the requirement.

In some embodiments, the charge pump 20 may operate in the first operation mode, in which the first output voltage V1 is generated, based on the first mode enable signal E1, or operate in the second operation mode, in which the second output voltage V2 is generated, based on the second mode enable signal E2. The first output voltage V1 is equal to the second output voltage V2. It should be understood that the charge pump 20 is controlled by the mode detection circuit 10, a waveform of a voltage provided by the charge pump 20 is sawtooth-shaped. As used herein, the voltages being equal means that target voltage values are equal.

It should be understood that the charge pump 20 operates, based on the first mode enable signal E1 or the second mode enable signal E2, in the first operation mode or the second operation mode to generate different currents. In some embodiments, the charge pump 20 may work at a first refresh frequency F1 corresponding to the first operation mode, or at a second refresh frequency F2 corresponding to the second operation mode. The first refresh frequency F1 is lower than the second refresh frequency F2. It should be understood that current leakage may occur in a load, such as a storage array, charged by the charge pump 20. Therefore, after a period of time, to maintain a required output voltage and a required output current, the output voltage of the charge pump 20 needs to be boosted to meet the required output current. The refresh frequency refers to a frequency for periodically boosting the output voltage of the charge pump via a clock signal with a particular frequency, a switch, and a capacitor, to enable the output voltage to reach a target value.

By using the semiconductor device provided in some embodiments of the present disclosure, it is possible for a NOR flash memory which reads data in a storage array sequentially, that the charge pump can be adjusted to be in the first operation mode to meet requirements with a low current when there is no need to switch a word line to access an area by an internal reading operation, and can be adjusted to be in a working mode only when there is a need to switch the word line, to maintain a high voltage required by the word line, so that a working current (that is, an output current sent to the word line when a particular operation, such as reading or standby, is performed) and a refresh frequency of the charge pump are significantly reduced, thereby greatly reducing power consumed by reading.

In addition, although the reading operation is used as an example in the foregoing description, it should be understood that the operations in the present disclosure may be other operations than the reading operation, such as a programming operation or any other operations relating to bias voltage switching of different word lines.

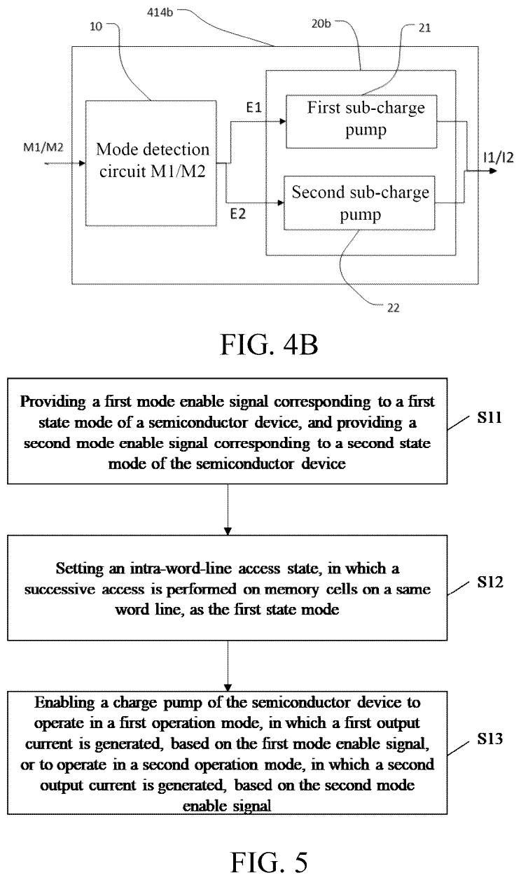

The following further describe a structure of the semiconductor device according to some embodiments of the present disclosure. FIG. 4A is a schematic block diagram of another embodiment of the voltage generator of the memory shown in FIG. 3. A semiconductor device 400 or a voltage generator 414a shown in FIG. 4A includes a mode detection circuit 10a and a charge pump 20. The mode detection circuit 10a further includes a first mode charge pump detection circuit 11, a second mode charge pump detection circuit 12, and a switch selection circuit 13. The first mode charge pump detection circuit 11 is configured to output the first mode enable signal E1. The second mode charge pump detection circuit 12 is configured to output the second mode enable signal E2. The switch selection circuit 13 is configured to select one of the first mode enable signal E1 and the second mode enable signal E2 to output to the charge pump 20 based on the first state mode or the second state mode.

In some embodiments, the first mode charge pump detection circuit 11 may receive a standby state provided by state logic (not shown) from the control logic unit 415 or by a register 416 as shown in FIG. 4A, or the first mark information, and these are taken as the first state mode signal M1 to enable the charge pump to start working. The second mode charge pump detection circuit 12 may receive a reading state provided by state logic (not shown) from the control logic unit 415 or by the register 416 as shown in FIG. 4A, or the second mark information, and these are taken as the second state mode signal M2 to enable the charge pump to start working.

In some embodiments, the first mode charge pump detection circuit 11 and the second mode charge pump detection circuit 12 respectively send the first mode enable signal E1 and the second mode enable signal E2, and send a control signal (not shown) to the switch selection circuit 13, to control a switch S1 and a switch S2 to turn on or turn off. In some other embodiments, the switch selection circuit 13 may be controlled by the control logic unit 415, to switch on or switch off the switch S1 or the switch S2.

In the standby mode corresponding to the first state mode M1, the switch S1 is turned on, the switch S2 is turned off, the first mode charge pump detection circuit 11 works normally, and the second mode charge pump detection circuit 12 is turned off. The first mode charge pump detection circuit 11 controls the charge pump through the first enable signal E1 to enable the charge pump 20 to generate and maintain a voltage (e.g., V1) higher than that of a power source, and generate the first current I1.

When a reading instruction is inputted, the second state mode M2 is activated, the switch S2 is turned on, the switch S1 is turned off, the second mode charge pump detection circuit works normally, and the first mode charge pump detection circuit 11 is turned off. The second mode charge pump detection circuit 12 controls the charge pump 20 through the second enable signal E2 to enable the charge pump 20 to generate and maintain a voltage (e.g., V2) higher than that of the power source, and generate the first current I2, to drive a word line corresponding to an address of the inputted reading instruction.

When each reading operation ends, whether there is a need to switch a word line for a next reading address is determined. If there is a need to switch the word line, the second mark information is generated, the second state mode M2 is activated, the switch S2 is turned on, the switch S1 is turned off, the second mode charge pump detection circuit 12 works normally, and the second enable signal E2 controls the charge pump 20, to enable the charge pump 20 to quickly respond to the output voltage of the charge pump 20, so as to satisfy a requirement of next reading data on a word line voltage. If there is no need to switch the word line, the first mark information is generated, the first state mode M1 is activated, the switch S1 is turned on, the switch S2 is turned off, the first mode charge pump detection circuit 11 works normally, the first enable signal E1 is sent to control the charge pump, to enable the charge pump 20 to provide enough driving force for a same word line corresponding to an address of the inputted reading instruction. Based on such configuration, the first mode charge pump detection circuit 11 can work in a lower response speed than the second mode charge pump detection circuit 12, and a frequency of activations of the charge pump 20 is also less. Therefore, a working current of the entire detection circuit can be lowered, and the refresh frequency of the charge pump which can work in the first operation mode at proper timing can be significantly reduced, thereby greatly reducing power consumed by reading.

In some embodiments, the first output voltage V1 is equal to the second output voltage V2. It should be understood that the charge pump 20 is controlled by the first mode charge pump detection circuit 11 or the second mode charge pump detection circuit 12, a waveform of an actual voltage provided by the charge pump 20 is sawtooth-shaped, and the voltages being equal means that target voltage values are equal.

FIG. 4B further shows another semiconductor device according to some embodiments of the present disclosure. FIG. 4B is a schematic block diagram of another embodiment of the voltage generator of the memory shown in FIG. 3. A semiconductor device or a voltage generator 414b shown in FIG. 4B includes a mode detection circuit 10 and a charge pump 20b. The charge pump 20b further includes a first sub-charge pump 21 and a second sub-charge pump 22. The first sub-charge pump 21 is configured to operate in the first operation mode based on the first mode enable signal E1. The second sub-charge pump 22 is configured to operate in the second operation mode based on the second mode enable signal E2.

Comparing FIG. 3 with FIG. 4B, it should be understood that the mode detection circuit 10 in FIG. 4B is identical to the mode detection circuit 10 in FIG. 3, which is not repeated herein. Moreover, it should be understood that the mode detection circuit 10 generates the first mode enable signal E1 and the second mode enable signal E2 corresponding to different states.

It should be understood that, in some embodiments, the mode detection circuit 10 in FIG. 4B may be identical to the mode detection circuit 10a in FIG. 4A, which is not repeated herein. Based on such configuration, the first mode detection circuit 11 is connected to the first sub-charge pump 21 through the switch S1, and the second mode detection circuit 12 is connected to the second sub-charge pump 22 through the switch S2.

In FIG. 4B, the charge pump 20b includes the first sub-charge pump 21 and the second sub-charge pump 22. The first sub-charge pump 21 operates in the first operation mode, in which the first output voltage V1 and the first output current I1 are generated, based on the first mode enable signal E1, and the second sub-charge pump 22 operates in the second operation mode, in which the second output voltage V2 and the second output current I2 are generated, based on the second mode enable signal E2. The first sub-charge pump 21 may be considered as the charge pump in the standby mode, and the second sub-charge pump 22 may be considered as the charge pump in an ordinary working mode. In this way, in the standby mode or a special reading operation mode in which there is no change in the word line, the first sub-charge pump 21 in the standby mode provides a bias voltage and a current to the word line; and in the ordinary reading mode or when there is a change in the word line, the second sub-charge pump 22 in a working mode provides the bias voltage and the current to the word line.

Because the NOR flash memory reads data in the storage array in sequence, when there is no need to switch a word line to access an area by an internal reading operation, the second sub-charge pump 22 in the working mode may be turned off, and the first sub-charge pump 21 in the standby mode may be turned on, to maintain a high voltage required by the word line, so that power consumed by reading is significantly reduced.

Corresponding to the memory which is used as an example of the semiconductor devices, some embodiments of the present disclosure further provide an operation method of the semiconductor device. FIG. 5 is a schematic flowchart of an operation method of a semiconductor device according to some embodiments of the present disclosure.

The operation method of the semiconductor device according to the embodiments of the present disclosure includes: providing a first mode enable signal E1 corresponding to a first state mode M1 of the semiconductor device 400, or providing a second mode enable signal E2 corresponding to a second state mode M2 of the semiconductor device 400 (S11); setting an intra-word-line access state in which a continuous access is performed on memory cells 43a on a same word line, as the first state mode M1 (S12); and enabling the charge pump 20 of the semiconductor device 400 to operate in the first operation mode, in which a first output current I1 is generated, based on the first mode enable signal E1, or in a second operation mode, in which a second output current I2 is generated, based on the second mode enable signal E2 (S13).

In some embodiments, the operation method further includes: setting an inter-word-line access state, in which a continuous access is performed on memory cells 42a on different word lines, as the second state mode M2.

In some embodiments, the operation method further includes: setting a standby state of the semiconductor device as the first state mode M1, and configuring the charge pump to be in the first operation mode.

In some embodiments, the operation method includes: setting a working state in which a reading instruction is received as the second state mode M2, and the continuous access is a continuous reading operation.

In some embodiments, the first output current I1 is smaller than the second output current I2.

In some embodiments, the operation method further includes: generating the first output voltage V1 in the first operation mode, and generating the second output voltage V2 in the second operation mode, wherein the first output voltage V1 is equal to the second output voltage V2.

In some embodiments, the providing of the first mode enable signal E1 or the second mode enable signal E2 includes: outputting, to the charge pump 20, the first mode enable signal E1 through the first mode charge pump detection circuit 11 based on the first state mode M1 and the second mode enable signal E2 through the second mode charge pump detection circuit 12 based on the second state mode M2; and selecting one of the first mode enable signal E1 and the second mode enable signal E2 by the switch selection circuit 13 to output to the charge pump 20.

In some embodiments, the enabling of the charge pump to operate in the first operation mode in which a first output current is generated or in a second operation mode in which a second output current is generated includes: receiving, by the first sub-charge pump 21, the first mode enable signal E1 to generate the first output current I1; and receiving, by the second sub-charge pump 22, the second mode enable signal E2 to generate the second output current I2.

By using the operation method(s) of a semiconductor device provided in embodiments of the present disclosure, it is possible for the NOR flash memory which reads data in a storage array sequentially, that the charge pump can be adjusted to be in the standby mode when there is no need to switch a word line to access an area by an internal reading operation, and can be adjusted to be in the ordinary working mode only when there is a need to switch the word line, to maintain a high voltage and current required by the word line. Based on such configuration, the refresh frequency of the charge pump is significantly reduced, thereby greatly reducing power consumed by reading.

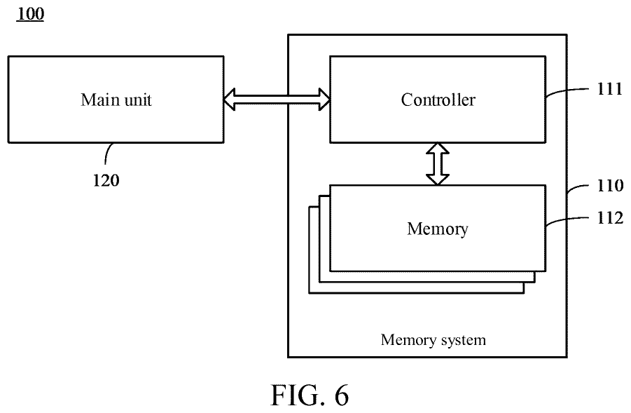

Finally, refer to FIG. 6. FIG. 6 is a schematic block diagram of an exemplary electronic system 100 with a memory system 110 according to some embodiments of the present disclosure. The electronic system 100 may be an electronic device, such as a mobile phone, a desktop computer, a laptop computer, a tablet computer, a vehicle computer, a game console, a printer, a positioning device, a wearable electronic device, a smart sensor, a virtual reality (VR) device, an augmented reality (AR) device or any other suitable electronic devices that have a memory.

As shown in FIG. 6, the foregoing electronic system 100 may include at least the memory system 110 and a main unit 120. The memory system 110 has a controller 111 and one or more memories 112. The memory(s) 112 may be the semiconductor device 400 as described above, and the main unit 120 may be a processor (for example, Central Processing Unit, CPU), or a system on a chip (SoC) (for example, Application processor, AP). Specifically, the main unit 120 may be configured to send data to the memory 112, or receive data from the memory 112.

According to some embodiments, the controller 111 may be coupled to the memory 112 and the main unit 120, and be configured to control the memory 112. Furthermore, the controller 111 can manage data stored in the memory 112, and communicate with the main unit 120. In some embodiments, the controller 111 may be designed to operate in a low duty cycle environment. The low duty cycle environment may be a universal serial bus (USB) flash drive, or another medium used in an electronic device, such as a personal computer, a digital camera, and a mobile phone.

The controller 111 can communicate with an external device (for example, the main unit 120) according to a particular communication protocol. For example, the controller 111 can communicate with an external device according to at least one interface protocol. The interface protocol may be, for example, a universal serial bus (USB) protocol, a multimedia card (MMC) protocol, a Peripheral Component Interconnect (PCI) protocol, a Peripheral Component Interconnect Express (PCI-E) protocol, an Advanced Technology Attachment (ATA) protocol, a serial ATA protocol, a parallel ATA protocol, a Small Computer System Interface (SCSI) protocol, an Enhanced Small Device Interface (ESDI) protocol, an Integrated Drive Electronics (IDE) protocol and a FireWire (FireWire) protocol.

A memory system provided in some embodiments of the present disclosure has the same beneficial effect as the foregoing memory 112 or semiconductor device 400.

According to the semiconductor device and the operation method thereof, and the memory system provided in the present disclosure, the semiconductor device includes a mode detection circuit and a charge pump. The mode detection circuit is configured to provide a first mode enable signal corresponding to a first state mode of the semiconductor device and provide a second mode enable signal corresponding to a second state mode of the semiconductor device. The charge pump is configured to operate in a first operation mode, in which a first output current is generated, based on the first mode enable signal, or to operate in a second operation mode, in which a second output current is generated, based on the second mode enable signal. The first state mode includes an intra-word-line access state in which a continuous access is performed on memory cells on a same word line. The charge pump can be adjusted to be in a standby mode when there is no need to switch a word line to access an area by an internal operation, and can be adjusted to be in a working mode only when there is a need to switch the word line, to maintain a high voltage required by the word line, so that a working current and a refresh frequency of the charge pump are significantly reduced, thereby greatly reducing power consumed by reading.

In conclusion, although the present disclosure has been disclosed with reference to preferred embodiments, the foregoing preferred embodiments are not intended to limit the present disclosure. A person skilled in the art may make some variations and modifications without departing from the spirit and scope of the present disclosure. Therefore, the protection scope of the present disclosure falls within the scope defined by the claims.

What is claimed is:

1. A semiconductor device, comprising:
a mode detection circuit configured to provide a first mode enable signal corresponding to a first state mode of the semiconductor device and provide a second mode enable signal corresponding to a second state mode of the semiconductor device; and
a charge pump configured to operate in a first operation mode, in which a first output current is generated, based on the first mode enable signal, or to operate in a second operation mode, in which a second output current is generated, based on the second mode enable signal,
wherein the first state mode comprises an intra-word-line access state in which a continuous access is performed on memory cells on a same word line.

2. The semiconductor device as claimed in claim 1, wherein the second state mode comprises an inter-word-line access state in which a continuous access is performed on memory cells on different word lines.

3. The semiconductor device as claimed in claim 1, wherein the first state mode further comprises a standby state, and the first operation mode comprises a standby mode.

4. The semiconductor device as claimed in claim 1, wherein the second state mode comprises a working state in which a reading instruction is received, the continuous access is a continuous reading operation, and the second operation mode comprises a working mode.

5. The semiconductor device as claimed in claim 1, wherein the first output current is smaller than the second output current.

6. The semiconductor device as claimed in claim 1, wherein a first output voltage is generated in the first operation mode, a second output voltage is generated in the second operation mode, and the first output voltage is equal to the second output voltage.

7. The semiconductor device as claimed in claim 1, wherein the charge pump works at a first refresh frequency in the first operation mode or works at a second refresh frequency in the second operation mode, and the first refresh frequency is lower than the second refresh frequency.

8. The semiconductor device as claimed in claim 1, wherein the mode detection circuit comprise:
a first mode charge pump detection circuit configured to output the first mode enable signal;
a second mode charge pump detection circuit configured to output the second mode enable signal; and
a switch selection circuit configured to select the first mode enable signal or the second mode enable signal to output to the charge pump based on the first state mode or the second state mode.

9. The semiconductor device as claimed in claim 1, wherein the charge pump comprises:
a first sub-charge pump configured to operate in the first operation mode based on the first mode enable signal, and
a second sub-charge pump configured to operate in the second operation mode based on the second mode enable signal.

10. An operation method of a semiconductor device, wherein the operation method comprises:
providing a first mode enable signal corresponding to a first state mode of the semiconductor device, and providing a second mode enable signal corresponding to a second state mode of the semiconductor device;
setting an intra-word-line access state, in which a continuous access is performed on memory cells on a same word line, as the first state mode; and
enabling a charge pump of the semiconductor device to operate in a first operation mode, in which a first output current is generated, based on the first mode enable signal, or to operate in a second operation mode, in which a second output current is generated, based on the second mode enable signal.

11. The operation method of the semiconductor device as claimed in claim 10, wherein the operation method further comprises: setting an inter-word-line access state, in which a continuous access is performed on memory cells on different word lines, as the second state mode.

12. The operation method of the semiconductor device as claimed in claim 10, further comprising: setting a standby state of the semiconductor device as the first state mode, and configuring the charge pump to be in the first operation mode.

13. The operation method of the semiconductor device as claimed in claim 10, further comprising: setting a working state in which a reading instruction is received as the second state mode, and the continuous access is a continuous reading operation.

14. The operation method of a semiconductor device as claimed in claim 10, wherein the first output current is smaller than the second output current.

15. The operation method of the semiconductor device as claimed in claim 10, further comprising:
generating a first output voltage in the first operation mode; and
generating a second output voltage in the second operation mode, wherein the first output voltage is equal to the second output voltage.

16. The operation method of the semiconductor device as claimed in claim 10, wherein the providing of the first mode enable signal and the second mode enable signal comprises:
outputting, to the charge pump, the first mode enable signal through a first mode charge pump detection circuit of the semiconductor device based on the first state mode or the second mode enable signal through a second mode charge pump detection circuit of the semiconductor device based on the second state mode.

17. The operation method of the semiconductor device as claimed in claim 10, wherein the charge pump of the semiconductor device comprises a first mode charge pump detection circuit and a second mode charge pump detection circuit, and the enabling of the charge pump of the semiconductor device to operate the first operation mode or in the second operation mode comprises:
receiving, by the first sub-charge pump, the first mode enable signal to generate the first output current; and
receiving, by the second sub-charge pump, the second mode enable signal to generate the second output current.

18. A memory system, comprising:
a semiconductor device, comprising:
a mode detection circuit configured to provide a first mode enable signal corresponding to a first state mode of the semiconductor device and provide a second mode enable signal corresponding to a second state mode of the semiconductor device; and
a charge pump configured to operate in a first operation mode, in which a first output current is generated, based on the first mode enable signal, or to operate in a second operation mode, in which a second output current is generated, based on the second mode enable signal,
wherein the first state mode comprises an intra-word-line access state in which a continuous access is performed on memory cells on a same word line; and
a controller configured to control the semiconductor device.

19. The memory system as claimed in claim 18, wherein the second state mode comprises an inter-word-line access state in which a continuous access is performed on memory cells on different word lines.

20. The memory system as claimed in claim 18, wherein the first state mode further comprises a standby state, and the first operation mode comprises a standby mode.
